(19) United States
(12) Patent Application Publication
(10) Pub. No.: US 2012/0018200 A1
(43) Pub. Date: Jan. 26, 2012

(54) TRANSPARENT CONDUCTIVE FILM FOR TOUCH PANEL AND METHOD FOR MANUFACTURING THE SAME

(75) Inventors: Sang Hwa Kim, Gyunggi-do (KR); Jong Young Lee, Gyunggi-do (KR); Yong Hyun Jin, Seoul (KR); Youn Soo Kim, Seoul (KR); Ji Soo Lee, Gyunggi-do (KR)

(73) Assignee: SAMSUNG ELECTRO-MECHANICS CO., LTD., Gyunggi-do (KR)

(21) Appl. No.: 12/901,690

(22) Filed: Oct. 11, 2010

(30) Foreign Application Priority Data
Jul. 26, 2010 (KR) 1020100071834

(51) Int. Cl. H05K 1/09; H05K 3/00; B82Y 40/00; B82Y 30/00

(52) U.S. Cl. 174/257; 427/98.4; 977/762; 977/952

(57) ABSTRACT

Disclosed herein are a transparent conductive film for a touch panel and a method for manufacturing the same. A transparent conductive film 100 for a touch panel according to the present invention includes a transparent substrate 110: a plurality of silver nanowires 120 formed on the transparent substrate 110 to be parallel with each other in one direction; and a transparent electrode 130 formed on the transparent substrate to apply the silver nanowires 120, whereby the silver nanowires 120 are formed in one direction of the transparent electrode 130 having the relatively higher surface resistance to make the surface resistance constant in all directions of the transparent conductive film 100 for the touch panel, thereby making it possible to increase touch sensitivity when a touch panel is manufactured.

### CROSS REFERENCE TO RELATED APPLICATION

This application claims the benefit of Korean Patent Application No. 10-2010-0071834, filed on Jul. 26, 2010, entitled “Transparent Conductive Film For Touch Panel And Manufacturing Method The Same,” which is hereby incorporated by reference in its entirety into this application.

### BACKGROUND OF THE INVENTION

1. Technical Field

The present invention relates to a transparent conductive film for a touch panel and a method for manufacturing the same.

2. Description of the Related Art

Alongside the growth of computers using digital technology, devices assisting the computers have also been developed, and personal computers, portable transmitters and other personal information processors execute processing of text and graphics using a variety of input devices such as a keyboard, a mouse and so on.

While the rapid advancement of the information-based society has been widening the use of computers more and more, there have been occurring the problems of it being difficult to efficiently operate products using only the keyboard and mouse as being currently responsible for the input device function. Thus, the demand for a device which is simple, does not malfunction, and has the capability to input easily is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD), a plasma display panel (PDP), an electroluminescence (EL) element or the like, or a cathode ray tube (CRT), so that a user selects the information desired while viewing the image display device.

Meanwhile, the touch panel is classifiable into a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. In particular, resistive and capacitive types are prevalently used.

However, the transparent conductive film used to manufacture the touch panel in the resistive type and the touch panel in the capacitive type according to the prior art has a problem in that the surface resistance thereof is different according to a measured direction. For example, when the transparent electrode is formed while feeding the transparent substrate in an X-axis direction, it is difficult to control forming of the transparent electrode in a Y-axis direction. Therefore, the surface resistance in the Y-axis direction of the transparent electrode is high as well as non-uniform, as compared to that in the X-axis direction. Therefore, the transparent conductive film for the touch panel according to the prior art has problems in that the electric conductivity thereof is not constant according to a direction and when the touch panel is manufactured using the transparent conductive film for the touch panel, the touch sensitivity is degraded.

### SUMMARY OF THE INVENTION

The present invention has been made in an effort to provide a transparent conductive film for a touch panel making the entire surface resistance thereof constant in all directions by forming a silver nanowire in one direction of the transparent electrode having a relatively higher surface resistance and a method for manufacturing the same.

A transparent conductive film for a touch panel according to a preferred embodiment includes: a transparent substrate: a plurality of silver nanowires formed on the transparent substrate to be parallel with each other in one direction; and a transparent electrode formed on the transparent substrate to apply the silver nanowires.

The transparent electrode is made of a conductive polymer.

The conductive polymer includes poly-3, 4-ethylenedioxythiophene/polystyrenesulfonate (PEDOT/PSS), polyaniline, polyacetylene, or polyphenylenevinylene.

When the surface resistance in an X-axis direction of the transparent electrode is higher than that in a Y-axis direction, the plurality of silver nanowires are formed in parallel with each other in the X-axis direction, and when the surface resistance in the Y-axis direction of the transparent electrode is higher than that in the X-axis direction, the plurality of silver nanowires are formed in parallel with each other in the Y-axis direction.

The plurality of silver nanowires are formed to have the same intervals therebetween.

The plurality of silver nanowires are formed to have the same diameter.

According to another embodiment of the present invention, there is provided a method for manufacturing a transparent conductive film for a touch panel, including: (A) providing a transparent substrate; (B) forming a plurality of silver nanowires on the transparent substrate to be parallel with each other in one direction; and (C) forming an transparent electrode on the transparent substrate to feed the transparent substrate vertically with respect to one direction and apply the silver nanowires.

At the forming the transparent electrode, the transparent electrode is made of the conductive polymer.

The conductive polymer includes poly-3, 4-ethylenedioxythiophene/polystyrenesulfonate (PEDOT/PSS), polyaniline, polyacetylene, or polyphenylenevinylene.

At the forming the plurality of silver nanowires, the plurality of silver nanowires are formed to have the same intervals therebetween.

At the forming the plurality of silver nanowires, the plurality of silver nanowires are formed to have the same diameter.

### BRIEF DESCRIPTION OF THE DRAWINGS

FIGS. 1A and 1B are perspective views of a transparent conductive film for a touch panel according to a preferred embodiment of the present invention;

FIG. 2 is a cross-sectional view taken along line A-A′ of the transparent conductive film for the touch panel shown in FIG. 1A; and

FIGS. 3 to 5 are cross-sectional views showing a process sequence of a method for manufacturing the transparent conductive film for the touch panel according to the preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Terms, “X-axis direction”, “Y-axis direction”, “one direction”, or the like, are used to represent the structural relationship between components but these components are not limited by the terms. Further, in describing the present invention, a detailed description of related known functions or configurations will be omitted so as not to obscure the subject of the present invention.

Hereinafter, preferred embodiments of the present invention will be described in detail with reference to the accompanying drawings.

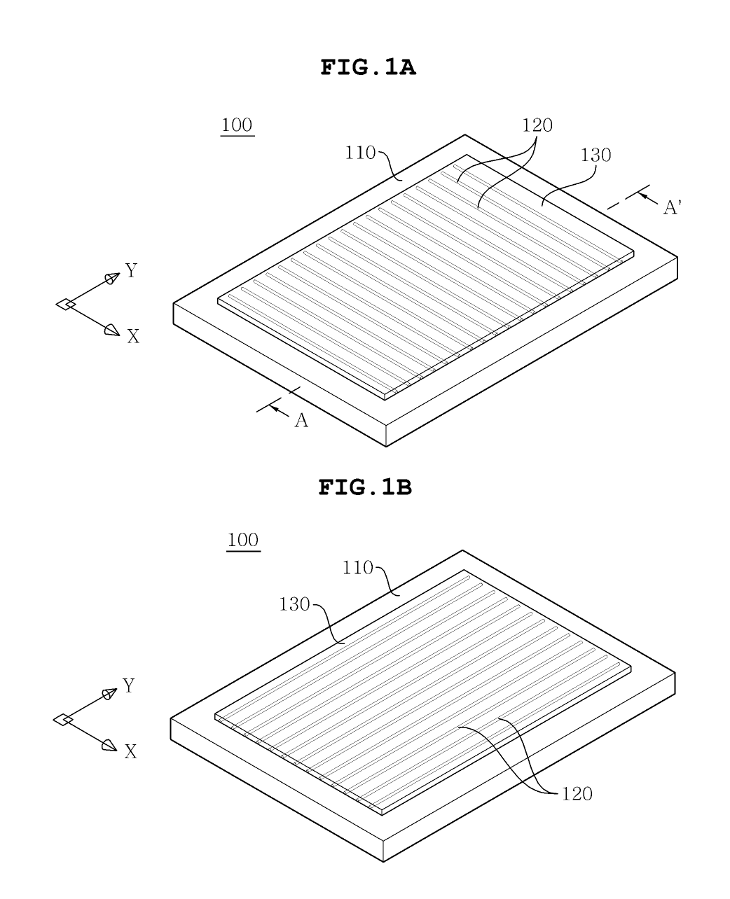

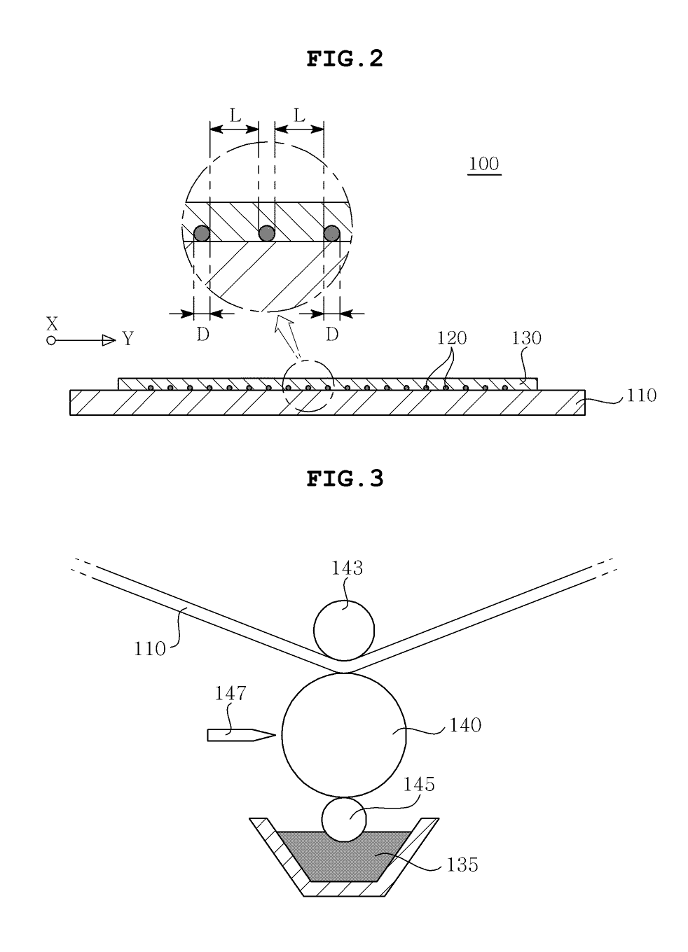

FIGS. 1A and 1B are perspective views of a transparent conductive film for a touch panel according to a preferred embodiment of the present invention and FIG. 2 is a cross-sectional view taken along line A-A′ of the transparent conductive film for the touch panel shown in FIG. 1A.

As shown in FIGS. 1 and 2, a transparent conductive film 100 for a touch panel according to a preferred embodiment of the present invention is configured to include a transparent substrate 110, a plurality of silver nanowires 120 formed on the transparent substrate 110 to be parallel with each other in one direction, and a transparent electrode 130 formed on a substrate to apply the silver nanowires 120.

The transparent substrate 110 is to provide an area in which the transparent electrode 130 and the silver nanowire 120 will be formed. In this configuration, the transparent substrate 110 should have a supporting force capable of supporting the transparent electrode 130 and the silver nanowire 120 and transparency enabling a user to recognize images provided from an image display device. When considering the above-mentioned supporting force and transparency, an example of a material of the transparent substrate 110 may include polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or reinforced glass, and so on, but is not necessarily limited thereto. Meanwhile, in order to improve an adhesion between the transparent substrate 110 and the transparent electrode 130, it is preferable that the transparent substrate 110 is subjected to a high frequency treatment or a primer treatment.

The silver nanowire 120 serves to supplement the electric conductivity of the transparent electrode 130 so that the entire surface resistance thereof is constant in all directions. The plurality of silver nanowires 120 are formed on the transparent substrate 110 to be parallel with each other in one direction. When forming the transparent electrode 130 and then, measuring the surface resistance of the transparent electrode 130 itself, the surface resistance is measured highly in a specific direction. The difference in the surface resistances is generally generated when forming the transparent electrode 130 while feeding the transparent substrate 110 in a machine direction. That is, since it is difficult to control forming of the transparent electrode 130 in a transverse direction vertical to the machine direction, the surface resistance of the transverse direction is high and non-uniform, as compared to that in the machine direction.

In order to supplement the difference in the above-mentioned surface resistances, it is preferable to form the silver nanowire 120 in a direction in which the surface resistance of the transparent electrode 130 is a relatively high. For example, when the surface resistance in the X-axis direction of the transparent electrode 130 is higher than that in the Y-axis direction (see FIG. 1A), the plurality of silver nanowires are formed in parallel with each other in the X-axis direction to lower the surface resistance in the X-axis direction, such that the surface resistances in the X-axis direction and the Y-axis direction may be the same. To the contrary, when the surface resistance in the Y-axis direction of the transparent electrode 130 is higher than that in the X-axis direction (see FIG. 1B), the plurality of silver nanowires are formed in parallel with each other in the Y-axis direction to lower the surface resistance in the Y-axis direction, such that the surface resistances in the Y-axis direction and the X-axis direction may be the same.

In addition, in order to uniformly lower the surface resistance, it is preferable that the plurality of silver nanowires 120 are formed to have the same intervals L therebetween (see FIG. 2). For example, when the plurality of silver nanowires 120 are formed in parallel with each other in the X-axis direction, it is preferable that the plurality of silver nanowires 120 are formed to have the same intervals L therebetween along the Y-axis direction. Further, it is preferable that the plurality of silver nanowires 120 are formed to have the same diameter D with respect to each other. In this case, the diameter D of the silver nanowire 120 is not specifically limited, but preferably 100 nm or less not to be recognized by the user. In this case, the meanings of ‘the same interval’ or ‘the same diameter’ do not imply that the interval L or the diameter D of the silver nanowire 120 is mathematically completely the same but include minute changes in interval or diameter due to processing errors, or the like, generated during a manufacturing process.

Meanwhile, the silver nanowire 120 implies the conductive material that enables the electrical contact at an atom-size. Silver Ag configuring the silver nanowire 120 has the highest electric conductivity among all the metals. Therefore, the silver nanowire 120 can implement the excellent effect to supplement the surface resistance of the transparent electrode 130.

The transparent electrode 130, which serves to recognize touched coordinates when being touched by the input unit, is formed on the transparent substrate 110 to apply the silver nanowire 120. In this case, the surface resistance of the transparent electrode 130 is highly measured in the specific direction. However, as described above, the plurality of silver nanowires 120 are formed in a direction in which the surface resistance of the transparent electrode 130 is high, thereby making it possible to lower the entire surface resistance, which can result in implementing a constant surface resistance in all directions. In addition, since the transparent substrate 110 is partitioned at a constant interval L by the silver nanowire 120, the transparent electrode 130 may be flatly formed. Meanwhile, the transparent electrode 130 may be formed using a conductive polymer having excellent flexibility and a simple coating process as well as indium tin oxide (ITO) that is commonly used. At this time, the conductive polymer includes poly-3, 4-ethylenedioxythiophene/polystyrenesulfonate (PEDOT/PS S), polyaniline, polyacetylene, polyphenylenevinylene, or the like.

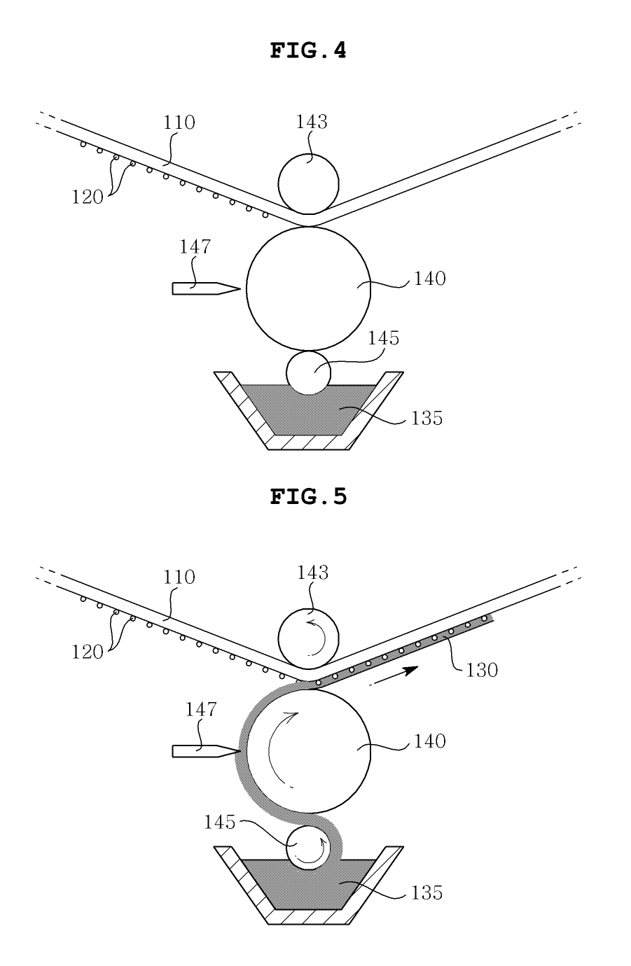

FIGS. 3 to 5 are cross-sectional views showing a process sequence of a method for manufacturing the transparent conductive film for the touch panel according to the preferred embodiment of the present invention.

As shown in FIGS. 3 to 5, a method for manufacturing the transparent conductive film for the touch panel according to the preferred embodiment of the present invention includes (A) providing the transparent substrate 110, (B) forming the plurality of silver nanowires 120 on the transparent substrate 110 to be parallel with each other in one direction, and (C) forming the transparent electrode 130 on the transparent substrate 110 to feed the transparent substrate 110 vertically to one direction and apply the silver nanowire 120. Hereinafter, the method for manufacturing the transparent conductive film for the touch panel is described based on a gravure printing method, which is by way of example only. The transparent conductive film for the touch panel may be formed by a dry etching process such as sputtering, evaporation, or the like, a wet etching process such as dip coating, spin coating, roll coating, spray coating, or the like, or a direct patterning process such as screen printing, inkjet printing or the like.

First, as shown in FIG. 3, the transparent substrate 110 is prepared. In this configuration, the transparent substrate 110 provides an area in which the transparent electrode 130 and the silver nanowire 120 will be formed and should have the supporting force capable of supporting the transparent electrode 130 and the silver nanowire 120 and the transparency enabling the user to recognize images provided from the image display device.

Next, as shown in FIG. 4, the plurality of silver nanowires 120 are formed on the transparent substrate 110 to be parallel with each other in one direction. In this case, the silver nanowire 120 serves to supplement the electric conductivity of the transparent electrode 130 to make the entire surface resistance constant all directions. In the process, one direction in which the silver nanowire 120 is formed is a transverse direction with respect to the machine direction of the transparent substrate 110 at the next process. The reason for forming the silver nanowire 120 in the transverse direction is that the surface resistance of the transparent electrode 130 is high in the transverse direction as compared to that in the machine direction when the transparent electrode 130 is formed at the subsequent process. That is, the silver nanowire 120 is formed in the transverse direction in which the surface resistance of the transparent electrode 130 is relatively high, such that the surface resistances of the transverse direction and the machine direction may be the same. In addition, the plurality of silver nanowires 120 are formed to have the same intervals L therebetween and the same diameter D, the surface resistance can be uniformly lowered in all directions. During the next process, when the transparent electrode 130 is formed, the planarization can be implemented (see FIG. 2).

Meanwhile, the silver nanowire 120 may be formed using a vapor-phase transport method. In this case, the vapor-phase transport method performs the heat treatment under atmosphere in which inert gas flows using a silver oxide as a precursor. Since the silver nanowire 120 is formed using the vapor-phase transport method, the silver nanowire 120 may have directivity in one direction. Next, as shown in FIG. 5, the silver nanowire 120 is applied by feeding the transparent substrate 110 and forming the transparent electrode 130 on the transparent substrate 110. As described above, the machine direction of the transparent substrate 110 and one direction forming the silver nanowire 120 are vertical to each other. The method for forming the transparent electrode 130 using the gravure printing method will be described in more detail. When the transparent substrate 110 forming the silver nanowire 120 is fed while being inserted between an impression cylinder 143 and a printing cylinder 140, the printing cylinder 140 receives a coating liquid 135 from an auxiliary cylinder 145 and applies it to the transparent substrate 110, thereby forming the transparent electrode 130. Meanwhile, one side of the printing cylinder 140 is provided with a doctor 147 to prevent excessive coating solution 135 from being applied to the transparent substrate 110. When forming the transparent electrode 130 through the gravure printing method, the surface resistance of the transparent electrode 130 itself is higher in the transverse direction than in the machine direction but the silver nanowire 120 is formed in the transverse direction, such that the entire surface resistance can be constant in all directions. In addition, at the above-mentioned process, the plurality of silver nanowires 120 are formed to have the same interval L therebetween (see FIG. 2) to partition the transparent substrate 110 to have the same intervals L therebetween, thereby making it possible to flatly form the transparent electrode 130 at the current process.

Meanwhile, the transparent electrode 130 may be formed using the conductive polymer including poly-3, 4-ethylenedioxythiophene/polystyrenesulfonate (PEDOT/PSS), polyaniline, polyacetylene, polyphenylenevinylene, or the like.

According to the embodiments of the present invention, it implements a transparent conductive film for a touch panel making the entire surface resistance thereof constant in all directions by forming a silver nanowire in one direction of a transparent electrode having a relatively higher surface resistance, thereby making it possible to increase the touch sensitivity when the touch panel is manufactured.

Although the preferred embodiments of the present invention have been disclosed for illustrative purposes, they are for specifically explaining the present invention and thus a transparent conductive film for a touch panel and a method for manufacturing the same according to the present invention are not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A transparent conductive film for a touch panel, comprising:
a transparent substrate;
a plurality of silver nanowires formed on the transparent substrate to be parallel with each other in one direction; and
a transparent electrode formed on the transparent substrate to apply the silver nanowires.

2. The transparent conductive film for a touch panel as set forth in claim 1, wherein the transparent electrode is made of a conductive polymer.

3. The transparent conductive film for a touch panel as set forth in claim 2, wherein the conductive polymer includes poly-3, 4-ethylenedioxythiophene/polystyrenesulfonate (PEDOT/PSS), polyaniline, polyacetylene, or polyphenylenevinylene.

4. The transparent conductive film for a touch panel as set forth in claim 1, wherein when the surface resistance in an X-axis direction of the transparent electrode is higher than that in a Y-axis direction, the plurality of silver nanowires are formed in parallel with each other in the X-axis direction, and when the surface resistance in the Y-axis direction of the transparent electrode is higher than that in the X-axis direction, the plurality of silver nanowires are formed in parallel with each other in the Y-axis direction.

5. The transparent conductive film for a touch panel as set forth in claim 1, wherein the plurality of silver nanowires are formed to have the same intervals therebetween.

6. The transparent conductive film for a touch panel as set forth in claim 1, wherein the plurality of silver nanowires are formed to have the same diameter.

7. A method for manufacturing a transparent conductive film for a touch panel, comprising:
(A) providing a transparent substrate;
(B) forming a plurality of silver nanowires on the transparent substrate to be parallel with each other in one direction; and
(C) forming a transparent electrode on the transparent substrate to feed the transparent substrate vertically with respect to one direction and apply the silver nanowires.

8. The method for manufacturing a transparent conductive film for a touch panel as set forth in claim 7, wherein at the forming the transparent electrode, the transparent electrode is made of the conductive polymer.

9. The method for manufacturing a transparent conductive film for a touch panel as set forth in claim 8, wherein the conductive polymer includes poly-3, 4-ethylenedioxythiophene/polystyrenesulfonate (PEDOT/PSS), polyaniline, polyacetylene, or polyphenylenevinylene.

10. The method for manufacturing a transparent conductive film for a touch panel as set forth in claim 7, wherein at the forming the plurality of silver nanowires, the plurality of silver nanowires are formed to have the same intervals therebetween.

11. The method for manufacturing a transparent conductive film for a touch panel as set forth in claim 7, wherein at the forming the plurality of silver nanowires, the plurality of silver nanowires are formed to have the same diameter.
